(19) United States
(12) Patent Application Publication
(10) Pub. No.: US 2025/0391475 A1
(43) Pub. Date: Dec. 25, 2025

(54) Programming Method for Non-Volatile Memory

(71) Applicant: Chengdu Analog Circuit Technology Inc., Sichuan (CN)

(72) Inventors: Tengfeng Wang, Sichuan (CN); Dong Hong, Sichuan (CN)

(21) Appl. No.: 19/209,966

(22) Filed: May 16, 2025

(30) Foreign Application Priority Data
Jun. 24, 2024 (CN) 202410821074.5

(51) Int. Cl. G11C 16/10; G11C 16/04; H10B 41/35; H10B 41/70

(52) U.S. Cl. CPC G11C 16/10; G11C 16/045; H10B 41/35; H10B 41/70

(57) ABSTRACT

Disclosed is a programming method for a non-volatile memory. The memory includes at least one memory cell. The memory cell includes: a P-well and an N-well adjacently located in a deep N-well, a first PMOS transistor and an NMOS capacitor respectively located in the N-well and P-well, and a floating gate covering the PMOS transistor and the NMOS capacitor. The first PMOS transistor in the memory cell is programmed through band-to-band tunneling.

### CROSS-REFERENCE TO RELATED APPLICATIONS

This application claims priority to Chinese Patent Application No. 202410821074.5, filed on Jun. 24, 2024, the entire content of which is incorporated herein by reference for all purposes.

### TECHNICAL FIELD

The present disclosure relates generally to a programming method for a non-volatile memory, and more particularly, to a band-to-band tunneling programming method for a non-volatile memory.

### BACKGROUND ART

A non-volatile memory includes a plurality of memory cells arranged in rows and columns. A memory cell generally includes a P-channel Metal Oxide Semiconductor (PMOS) transistor and/or an N-channel metal oxide semiconductor (NMOS) transistor, and some further include a MOS coupling capacitor.

Currently, many programming methods for a non-volatile memory are as follows: A PMOS transistor or an NMOS transistor in a memory cell injects negative charges into a floating gate of the transistor through channel hot electron tunneling. An advantage of the programming method is as follows: The method can be applied to a relatively large programming voltage range. As long as a source-drain voltage difference and a gate-drain voltage difference of an MOS transistor device meets a turn-on condition and enters a saturation state, programming can be implemented. In addition, the method is applicable to a variety of transistor devices manufactured by using different process platforms. A disadvantage of the programming method is that a charge pump with a high driving capability is required, and programming power consumption is high; and an area of the charge pump with the high driving capability is relatively large, which is not conducive to reduction of a size of the memory.

In the channel hot electron tunneling programming method, positive and negative voltages required for programming the memory are usually generated by a Dickson charge pump circuit. During programming through injection of hot electrons into a floating gate of a transistor in the memory cell induced by channel hot holes of the transistor, it is required to create a high transverse electric field in the channel, to accelerate carriers to generate a saturated hole current required for the programming. The high transverse electric field in the channel and the large channel current require the charge pump to have a high positive and negative voltage driving capability, and power consumption is high.

A charge pump is a voltage multiplier circuit that generates a desired voltage and driving capability by connecting multiple stages of MOS transistor capacitors in series and parallel. The charge pump with the high driving capability requires more larger MOS transistors to be connected in parallel, and takes up a relatively large area. The charge pump usually occupies a relatively large area in the memory, such as a single-layer polysilicon PMOS memory, and especially in a small-capacity (for example, 256×8 bits) memory, the area exceeds 50%. Therefore, the charge pump with the high driving capability hinders reduction of the size of the memory.

Therefore, in the industry, there is requirement for a new programming method, to further reduce power dissipation and facilitate to reduce the area of the memory.

### SUMMARY OF THE DISCLOSURE

According to a first aspect of the disclosure, a programming method for a non-volatile memory is provided. The memory includes: at least one non-volatile memory cell built on a P-type substrate, where each non-volatile memory cell includes: a deep N-well located in the P-type substrate, where a P-well and an N-well are located in the deep N-well; a first P-channel Metal Oxide Semiconductor (PMOS) transistor located in the N-well; an N-channel metal oxide semiconductor (NMOS) capacitor located in the P-well, where the NMOS capacitor includes an N+ coupling region located in the P-well; and a floating gate covering the PMOS transistor and the NMOS capacitor. The programming method is: programming the first PMOS transistor in the non-volatile memory cell through band-to-band tunneling, the programming method including the following steps: (a) causing a potential of the N-well to be greater than a potential of a terminal of the first PMOS transistor, where a potential difference between the N-well and the terminal forms a reverse bias voltage on a PN junction at an interface between the N-well and the terminal, and the reverse bias voltage causes electrons in the PN junction to tend to concentrate on a side of the PN junction that is close to the N-well; (b) causing a potential on the floating gate of the first PMOS transistor to be greater than a potential of the terminal of the first PMOS transistor, where a potential difference between the floating gate of the first PMOS transistor and the terminal of the first PMOS transistor creates a strong electric field with an electric field strength greater than 8 MV/cm between the floating gate and the terminal; and (c) implementing the programming by injecting, into the floating gate of the first PMOS transistor, the electrons on the side of the PN junction that is close to the N-well at the interface between the N-well and the terminal, under an action of the strong electric field.

### BRIEF DESCRIPTION OF THE DRAWINGS

The implementations of embodiments are described by way of example, but are not limited to the examples shown in the accompanying drawings. The same numerals in the accompanying drawings denote the same or similar elements.

FIG. 1a to FIG. 1c respectively show a top view, a sectional view along section line A-A, and a sectional view along section line B-B of a memory cell of a non-volatile memory using a programming method in the present disclosure;

FIG. 2 shows a relationship between a reverse bias voltage and an output current on a PN junction between a terminal of a first P-channel Metal Oxide Semiconductor (PMOS) transistor and an N-well of the memory cell shown in FIG. 1 in an implementation;

FIG. 3a shows a relationship between a programming voltage (VPP) and a readout current after programming of a first PMOS transistor of the memory cell shown in FIG. 1 in an implementation, for different programming times (10 μs/100 μs/1 ms/10 ms);

FIG. 3b and FIG. 3c respectively show relationships between a potential of a control gate and a readout current in a readout operation after the first PMOS transistor of the memory cell shown in FIG. 1 is programmed for different time periods at programming voltages (VPP) of 9.5 V and 10.5 V;

FIG. 3d shows a relationship between a potential of a control gate and a readout current in a readout operation after the first PMOS transistor in the memory cell shown in FIG. 1 is programmed and erased 1/10/100/1000/10K times;

FIG. 4 shows an array of memory cells shown in FIG. 1 that are arranged in two rows and two columns;

FIG. 5 shows bias signals connected to the array shown in FIG. 4 during different operations of the array;

FIG. 6 shows a top view of a memory cell of another non-volatile memory using a programming method in the present disclosure;

FIG. 7 shows a sectional view of the memory cell shown in FIG. 6 along section line A-A;

FIG. 8 shows a sectional view of the memory cell shown in FIG. 6 along section line B-B;

FIG. 9 shows a sectional view of the memory cell shown in FIG. 6 along section line C-C;

FIG. 10 shows a memory array of memory cells shown in FIG. 6 that are arranged in two rows and two columns; and

FIG. 11 shows bias signals connected to the array shown in FIG. 10 during different operations of the array.

Other features of the implementations of the present disclosure can be clearly understood from the accompanying drawings and the following detailed description.

### DETAILED DESCRIPTION OF EMBODIMENTS

In the related art, when programming is performed through channel hot electron tunneling, a charge pump with a high positive and negative voltage driving capability is required to implement a high transverse electric field in a channel. In addition, the channel has a large operating current that is generally greater than 5 mA, and programming power consumption is relatively high. When the programming is performed through band-to-band tunneling in the present disclosure, there is a single voltage requirement, no negative voltage may be required, and there is a low requirement for a driving capability of a charge pump. In addition, a programming current is extremely small that is generally less than 100 μA, up to the order of nA/bit. Programming power consumption of the memory is significantly reduced.

In the programming method in the present disclosure, no charge pump with a high driving capability is required, and an area of the charge pump is significantly reduced compared to the existing channel hot electron tunneling programming method. For example, when a 5V transistor device using a 0.18 μm process platform is programmed through band-to-band tunneling in the present disclosure, an area required for a charge pump is only 0.03 mm². When programming is performed through channel hot electron tunneling, an area required for a charge pump is up to 0.15 mm². Based on the programming method in the present disclosure, an area of the charge pump occupied in the memory is significantly reduced. This is very conducive to reduction of a size of the memory.

In addition, based on the programming method in the present disclosure, no charge pump with the high driving capability is required, thereby facilitating design of the memory. The programming method is more competitive in applications of low-power small-capacity memories.

A non-volatile memory in the present disclosure includes a one-time programmable memory and a multi-time programmable erasable memory. In an example, the non-volatile memory is an electrically erasable programmable non-volatile memory.

The memory in the present disclosure may be manufactured by using a common process in a silicon chip factory with a deep submicron technology, for example, a 40 nm to 350 nm process platform. In an example, the memory may be manufactured by using a BCD (a bipolar transistor, a CMOS device, and a DMOS device are fabricated on a same chip) process platform.

A memory cell in the memory in the present disclosure has a deep N-well, to isolate the memory cell from a substrate. A first P-channel Metal Oxide Semiconductor (PMOS) transistor and an N-channel metal oxide semiconductor (NMOS) capacitor in the memory cell are respectively located in an N-well and a P-well adjacently arranged in the deep N-well. The PMOS transistor includes a PMOS gate oxide and a gate covering the PMOS gate oxide. The NMOS capacitor includes an N+ coupling region located in the P-well, a gate oxide, and a gate covering the gate oxide. The N+ coupling region is formed through N+ source/drain ion injection. The gate of the NMOS capacitor extends and is combined with the PMOS gate, forming a floating gate of the memory cell. The floating gate covers the PMOS transistor and the NMOS capacitor, but does not cover the N+ coupling region of the NMOS capacitor. In an example, the floating gate is a single-layer polysilicon gate. The N+ coupling region connects a control word line (WL) to a control gate of the memory cell. The control gate is formed by a channel region of the NMOS capacitor. A potential is applied to the N+ coupling region, and may be coupled to the floating gate through the channel region of the NMOS capacitor. Therefore, a structure of the coupling capacitor includes a floating gate that partially overlaps an active region in the P-well, a gate oxide below, and an NMOS channel. To improve the efficiency of the coupling gate, a capacitance of the coupling capacitor is made much greater than a capacitance of the PMOS gate.

The memory cell of the memory in the present disclosure may further include a second PMOS transistor connected to the first PMOS transistor in series and located in the N-well. The second PMOS transistor also includes a gate oxide and a gate covering the gate oxide. In an example, the gate is a single-layer polysilicon gate, and is connected to an access word line (WL) signal. The N+ coupling region of the NMOS capacitor connects a control gate signal (CG) to the control gate of the memory cell, and the control gate is formed by the channel region of the NMOS capacitor. The second PMOS transistor serves as a selector of the programmable first PMOS transistor, and does not participate in the programming of the memory cell.

The programming of the memory cell occurs in the first PMOS transistor, and a programming method is band-to-band tunneling. One terminal (for example, a source) of the first PMOS transistor participates in the programming. The other terminal (for example, a drain) may or may not participate in the programming. In an example, the other terminal does not participate in the programming. In another example, the terminal that does not participate in the programming is in a floating state during the programming.

When the programming begins, for the terminal of the first PMOS transistor that participates in the programming, step (a) is first performed: causing a potential of the N-well to be greater than a potential of the terminal, where a potential difference between the N-well and the terminal forms a reverse bias voltage on a PN junction at an interface between the N-well and the terminal, and the reverse bias voltage causes electrons in the PN junction to tend to concentrate on a side of the PN junction that is close to the N-well.

A larger potential difference between the N-well and the terminal of the first PMOS transistor that participates in the programming is more conducive to causing more electrons in the PN junction to concentrate on the side close to the N-well. An upper limit of the potential difference is less than an avalanche breakdown voltage of the PN junction. In an example, the potential difference is 0.1 V to 1.0 V less than the avalanche breakdown voltage of the PN junction at the interface between the N-well and the terminal of the first PMOS transistor that participates in the programming. In another example, the potential difference is 0.1 V to 0.7 V less than the avalanche breakdown voltage. In another example, the potential difference is 0.1 V to 0.5 V less than the avalanche breakdown voltage. In an example, the potential difference may be 5.0 V to 10.5 V. In another example, the potential difference may be 7.0 V to 10.5 V. In another example, the potential difference may be 9.0 V to 10.5 V. When the potential difference is close to the avalanche breakdown voltage of the PN junction, the electrons on the side of the PN junction that is close to the N-well are more easily injected into the floating gate under an action of an electric field, leading to a good programming effect, a short programming time, a good programming convergence, and a high programming efficiency.

A circuit design of the memory in the related art may ensure that the PN junction may be prevented from being irreversibly damaged and broken down while the programming succeeds, in the case that the foregoing potential difference is close to but does not exceed the avalanche breakdown voltage of the PN junction. In addition, the inventors found that when the programming is performed in the case that the potential difference is less than the avalanche breakdown voltage of the PN junction, a number of programming times of the memory may reach 10,000, which is sufficient to meet application requirements.

Steps (b) and (c) are then performed in sequence: causing a potential on the floating gate of the first PMOS transistor to be greater than a potential of the terminal of the first PMOS transistor that participates in the programming, where a potential difference between the floating gate of the first PMOS transistor and the terminal of the first PMOS transistor creates a strong electric field with an electric field strength greater than 8 MV/cm between the floating gate and the terminal. Such a strong electric field may cause the electrons on the side of the PN junction that is close to the N-well to undergo band-to-band tunneling and to be injected into the floating gate, to implement the programming.

In an example, the electric field created by the potential on the floating gate of the first PMOS transistor and the potential of the terminal participating in the programming is greater than 8 MV/cm. For example, the potential on the floating gate may be 6.5 V to 10.5 V. For another example, the potential on the floating gate may be 7.0 V to 10.5 V. For another example, the potential on the floating gate may be 9.0 V to 10.5 V.

The potential on the floating gate of the first PMOS transistor is obtained by coupling the potential applied to the N+ coupling region of the NMOS capacitor through a channel of the NMOS capacitor. To improve the coupling efficiency, the capacitance of the NMOS capacitor is much greater than the capacitance of the PMOS gate. A gate capacitance value of the NMOS capacitor may be 1 to 10 times a gate capacitance value of the first PMOS transistor. In an example, the gate capacitance value of the NMOS capacitor may be 1.5 to 7 times the gate capacitance value of the first PMOS transistor. In an example of the disclosure, the gate capacitance value of the NMOS capacitor may be 2 to 5 times the gate capacitance value of the first PMOS transistor.

During the programming, the potential applied to the N+ coupling region in an example is less than or equal to the potential of the N-well. This may prevent an electric leakage between the P-well and the N-well. In another example, the potential applied to the N+ coupling region is the same as the potential of the N-well.

In an example, the terminal of the first PMOS transistor that participates in the programming has a potential of 0 V during the programming, and the other terminal not participating in the programming is in a floating state during the programming. The terminal participating in the programming may be referred to as a source, and the other terminal not participating in the programming is referred to as a drain.

In the programming method in the present disclosure, steps (a) and (b) may be implemented sequentially, in reverse order, or simultaneously. Regardless of an order of steps (a) and (b), step (c) is always performed after steps (a) and (b).

The foregoing non-volatile memory cell in the present disclosure may further include a second PMOS transistor located in the N-well. One terminal of the second PMOS transistor is coupled to the terminal (for example, the drain) of the first PMOS transistor that does not participate in the programming, and the other terminal does not participate in the programming.

In the case that the source of the first PMOS transistor participates in the programming, the drain of the first PMOS transistor is coupled to a source of the second PMOS transistor. Therefore, a drain of the second PMOS transistor does not participate in the programming, or a channel of the second PMOS transistor is not conducting during the programming. In an example, the drain of the second PMOS transistor is in a floating state during the programming.

In an example, during the programming, a potential of a gate of the second PMOS transistor is the same as the potential of the N-well. This may avoid affecting a service life of a gate oxide layer and a service life of the transistor due to formation of electrical stress on a gate oxide layer of the second PMOS transistor.

Depending on actual applications, the first PMOS transistor and the second PMOS transistor may be the same or different. In an example, the two are the same.

In an implementation, for a memory cell that does not include the second PMOS transistor, during the programming, the potential of the N-well is the same as the potential of the N+ coupling region, the potential of the terminal of the first PMOS transistor that participates in the programming is 0 V, and the terminal not participating in the programming is in a floating state. For the memory cell including the second PMOS transistor, during the programming, the potential of the N-well and the potential of the N+ coupling region are the same as the potential of the gate of the second PMOS transistor, the potential of the terminal of the first PMOS transistor that participates in the programming is 0 V, and a terminal of the second PMOS transistor that does not participate in the programming is in a floating state. In this case, there is a single voltage requirement during the programming, and an operation is very convenient.

The following describes the programming method for a non-volatile memory in the present disclosure in further detail with reference to specific embodiments. Although the following description is provided with reference to the specific embodiments, it is evident that various adjustments and changes may be made to the embodiments without departing from the essence and broad scope of various implementations of the present disclosure. In addition, although the embodiments and the accompanying drawings provide specific voltage values, it should be understood that these values are not necessarily precise, but are used to express a general concept of a biasing approach.

The memory in embodiments is an electrically erasable programmable non-volatile memory, and is manufactured by using a 180 nm BCD process platform. The first and second PMOS transistors in the memory cell are the same. The two transistors and the NMOS capacitor are 5 V devices, a thickness of a gate oxide layer is 120 angstroms, and a floating gate of the transistor is single-layer polysilicon.

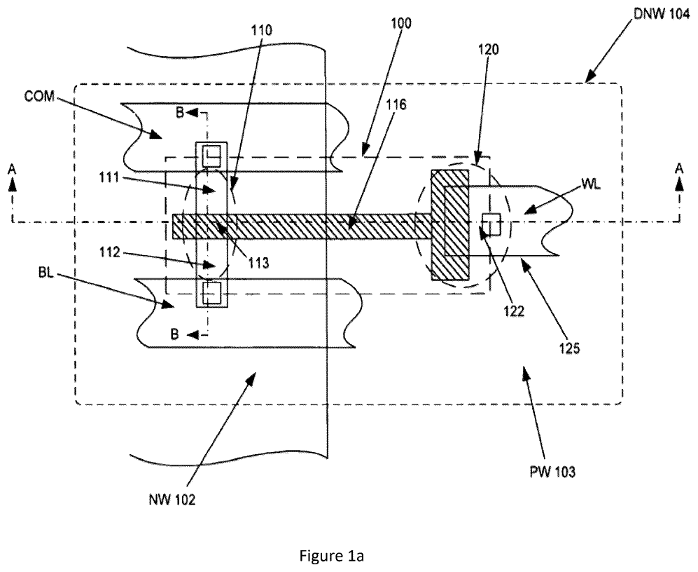

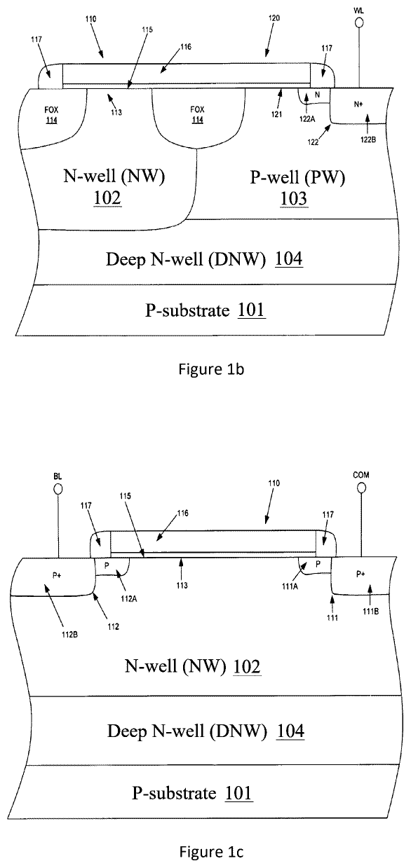

FIG. 1a shows a top view of a non-volatile memory cell 100 of a memory according to the embodiment. FIG. 1b and FIG. 1c respectively show sectional views along section lines A-A and B-B in FIG. 1a of the memory cell.

In this embodiment, the non-volatile memory cell 100 is built on a P-type silicon substrate 101. A deep N-well 104 is disposed in the P-substrate 101, to electrically isolate the memory cell from the substrate. An N-well 102 and a P-well 103 are closely adjacent to each other and are disposed in the deep N-well 104. A first PMOS transistor 110 is disposed in the N-well 102. The PMOS transistor 110 includes a P-type drain 112 and a source 111. The drain 112 includes a lightly doped region 112A and a heavily doped P+ contact region 112B. The source 111 includes a lightly doped region 111A and a heavily doped P+ contact region 111B.

The source 111 is connected to a common line (COM), and the drain 112 is connected to a bit line (BL). The transistor 110 is surrounded by a shallow trench, and the shallow trench is filled with a thick field oxide 114. A channel region 113 is between the source 111 and the drain 112. A gate oxide layer 115 covering the channel region 113 has a thickness of 120 angstroms. A conductively doped polysilicon gate is placed on top of the gate oxide layer 115, forming a floating gate 116 of the first PMOS transistor.

The floating gate 116 and the gate oxide layer 115 extend to the P-well 103, and partially overlap an active region 125, forming an upper plate and a dielectric of an NMOS capacitor 120. The floating gate 116 also partially overlaps a charge injection element 122, and the charge injection element 122 includes a lightly doped N region 122A and a heavily doped N+ region 122B. The floating gate 116 is surrounded by a sidewall spacer 117, and the sidewall spacer 117 is usually formed by silicon nitride or silicon oxide.

When an N+ region or a P+ region is formed, the sidewall spacer 117 prevents an N+ injected substance or a P+ injected substance from entering a lightly doped N region or P region. The charge injection element 122 is connected to a word line (WL), and the word line (WL) is also connected to the P-well through a P+ contact region (not shown). During an operation, when a potential of the floating gate 116 is less than that of the WL, a voltage difference therebetween is greater than a threshold voltage of the NMOS capacitor, a P-well region 121 below the floating gate is inverted, and electrons emitted by the injection element 122 form an electron layer in the region 121, thereby forming a lower plate of the NMOS capacitor 120. The lower plate formed by region 121 is connected to the WL through the injection element 122. The N+ coupling region connects a control word line (WL) to a control gate of the memory cell, and the control gate is formed by the channel region of the NMOS capacitor. A potential is applied to the N+ coupling region, and may be coupled to the floating gate through the channel region of the NMOS capacitor.

All processing steps required to form the memory cell 100 are those used in a logic process to form other on-chip circuits. No additional processing steps are required. A gate capacitance value of the NMOS capacitor 120 may be 3.4 times a gate capacitance value of the first PMOS transistor 110.

During programming of the memory cell 100, the source 111 of the first PMOS transistor 110 participates in the programming, and the drain 112 does not participate and is in a floating state. First, a potential of the N-well and a potential of the deep N-well is driven to a VPP, the COM is 0 V, the BL floats, and then the WL is driven to a VPP for programming. The VPP is a positive value. Because the COM is 0 V, the VPP may also be referred to as a programming voltage.

The potential of the N-well is a positive VPP, and potentials of the doped regions 111A and 111B of the source 111 of the first PMOS transistor are 0 V. There is a reverse bias voltage VPP on a PN junction between the N-well and the doped region of the source of the first PMOS transistor, causing electrons in the PN junction to tend to concentrate on a side of the PN junction that is close to the N-well. Then, for the floating gate 116, a positive potential that is 0.95 times the VPP is obtained by coupling the potential VPP of the N+ coupling region of the NMOS capacitor. A strong electric field with a strength greater than 8 MV/cm is created between the floating gate 116 and the doped region of the source 111 of the first PMOS transistor, so that the electrons on the side of the PN junction that is close to the N-well undergo band-to-band tunneling and jump to the floating gate, thereby completing programming.

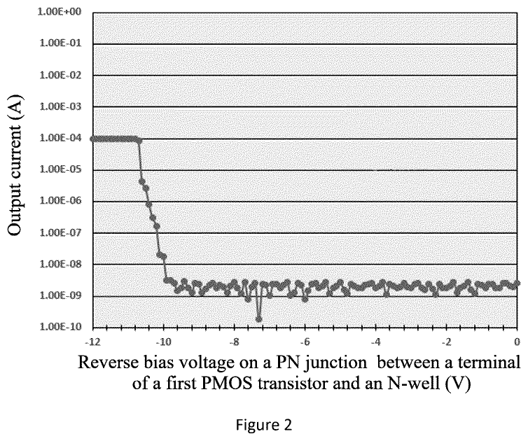

FIG. 2 shows a relationship between a reverse bias voltage and an output current of the reverse bias voltage at a PN junction between a doped region of a source of a first PMOS transistor 110 and an N-well of a memory cell 100. In the figure, the abscissa is a potential of the source, and the ordinate is the output current (amps). In this case, a potential of the N-well is 0 V. As can be seen from FIG. 2, the output current of the reverse bias voltage increases rapidly when the reverse bias voltage of the PN junction is above 10.2 V. In this case, a large number of electron-hole pairs are generated, and an avalanche breakdown of the junction occurs when the reverse bias voltage exceeds about 10.6 V. Programming is performed at a voltage near the breakdown voltage before the avalanche breakdown. A large number of electrons tend to concentrate on a side of the PN junction that is close to the N-well, thereby facilitating improving the programming efficiency, shortening a programming time, and presenting a good convergence. Therefore, In an example, the VPP is a bias voltage value of 10.05 V to 10.5 V before the avalanche breakdown occurs in the PN junction. When the programming voltage VPP is close to the avalanche breakdown of the PN junction (the large number of electron-hole pairs are generated), a number of programming times of the memory is not affected. The inventor has experimentally proved that when the programming is performed at a voltage close to the avalanche breakdown voltage of the PN junction, for example, 10.5 V, a service life of the memory may reach 10,000 times.

When the VPP is set to 10.5 V, an electric field with a strength of 8.3 MV/cm is created between a floating gate 116 and a doped region of the source 111 of the first PMOS transistor, and the strength is greater than 8 MV/cm. In this case, band-to-band tunneling may be performed on the electrons to the floating gate.

During the programming, the electrons are injected into the floating gate of the memory cell, resulting in a decrease in a threshold voltage of the first PMOS transistor, so that it is easier to conduct a channel of the transistor, and a readout current during a readout operation is caused to increase.

During a readout operation after the programming, a potential is applied to a control gate, so that a difference between a potential of the floating gate of the first PMOS transistor and the potential of the N-well is greater than the threshold voltage of the transistor, thereby conducting the channel of the transistor. In addition, a potential difference exists between the source and a drain of the transistor, thereby forming a channel readout current that flows out from a bit line.

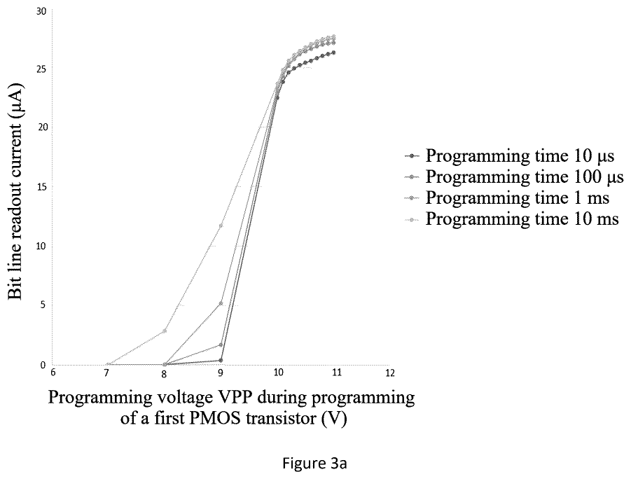

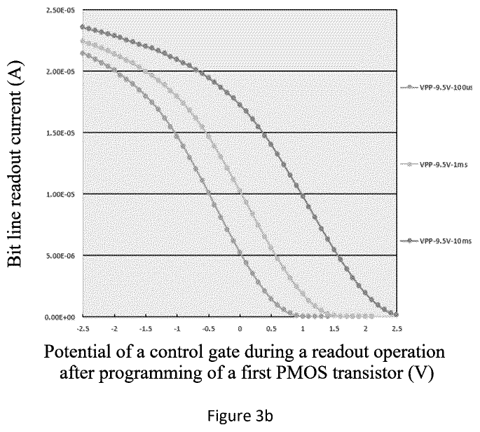

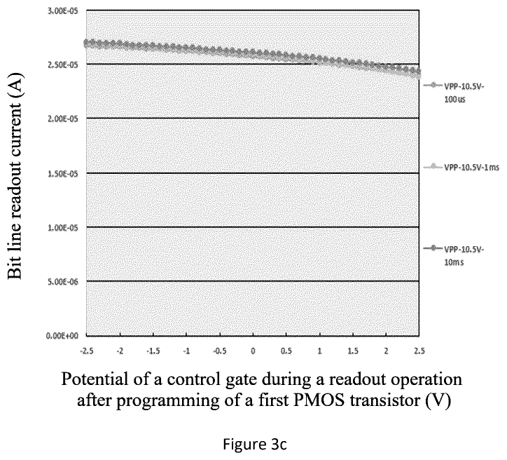

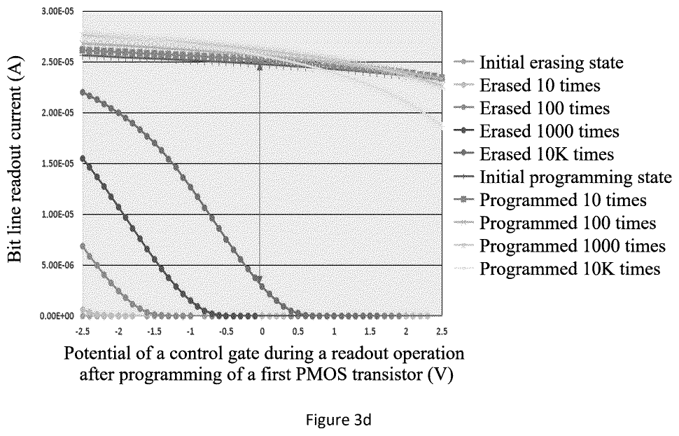

FIG. 3a shows a relationship between a programming voltage (VPP) and a cell readout current after programming of a first PMOS transistor 110 of a memory cell 100, for different programming times (10 μs/100 μs/1 ms/10 ms). As can be seen from FIG. 3a, when the VPP is greater than or equal to 9 V, a programming effect is relatively significant. When the VPP is 9V and a programming time is 10 ms, the channel readout current after the programming is greater than 10 uA, and is relatively significant. When the VPP increases in a range of 9 V to 10 V, the channel readout current increases sharply, and a programming speed significantly increases. When the VPP exceeds 10 V, the channel readout current is greater than 20 uA after the programming is performed for 10 μs. In this case, the programming has tended to saturation and has a good convergence. Increasing the programming time or voltage will not significantly improve the programming effect.

FIG. 3b and FIG. 3c respectively show relationships between a potential of a control gate and a readout current in a readout operation after a first PMOS transistor 110 in a memory cell 100 is programmed for different time periods by using VPPs of 9.5 V and 10.5 V. As can be seen from FIG. 3b and FIG. 3c, when programming is performed by using the VPP of 9.5 V, a channel readout current flowing from a bit line for different programming times has a poor convergence. However, when the programming is performed by using the VPP of 10.5 V, a channel readout current for different programming times has a good convergence.

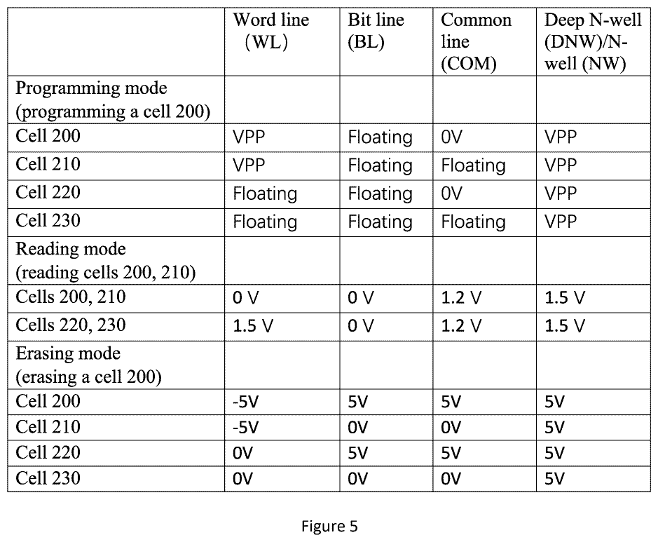

FIG. 3d shows a relationship between a potential of a control gate and a readout current in a readout operation after a first PMOS transistor 110 in a memory cell 100 is programmed and erased 1/10/100/1000/10K times. Programming and erasing conditions are respectively the same as those of a cell 200 in FIG. 5, where a VPP is 10.5 V. As can be seen from FIG. 3d, after programming and erasing are repeated 10K, a difference between programming and erasing currents (a readout window) is still greater than 20 uA, thereby meeting circuit design requirements (a difference between programming and erasing current circuit requirements is greater than or equal to 3 uA).

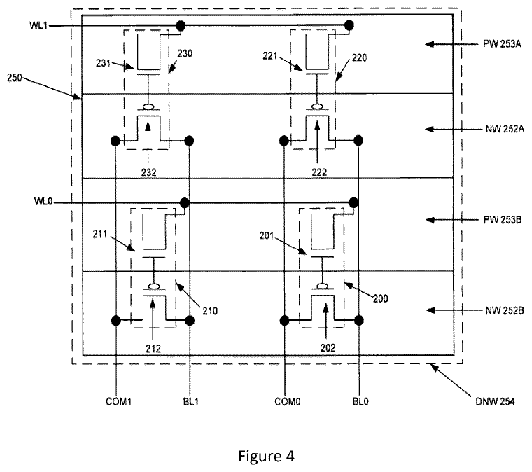

In most applications, a plurality of non-volatile cells 100 may be placed together to form a memory array. For description by way of example, FIG. 4 describes and shows an operation of a 2×2 memory array 250. The array includes four memory cells arranged in two rows and two columns. By increasing and/or decreasing a number of rows and/or columns, arrays of different sizes may be formed. The memory array 250 includes memory cells 200, 210, 220, and 230. The memory array 250 further includes NMOS capacitors 201, 211, 221, and 231, and first PMOS transistors 202, 212, 222, and 232.

In an implementation, WLs of the memory cells 200 and 210 are connected to a WL 0, forming a memory row; and WLs of the memory cells 220 and 230 are connected to a WL 1, forming another memory row. A common line (COM) and a bit line (BL) of the cells 200 and 220 are respectively connected to a COM 0 and a BL 0, forming a memory column. Similarly, a common line (COM) and a bit line (BL) of the cells 210 and 230 are respectively connected to a COM 1 and a BL 1, forming another memory column. The memory array is built in a P-type substrate. Deep N-wells of all the memory cells are combined, forming a single deep N-well (for example, a deep N-well 254). N-wells and P-wells of memory cells in a memory row are combined respectively. Therefore, each memory row includes one N-well (such as an NW 252A or an NW 252B) and one P-well (such as a PW 253A or a PW 253B).

The N-wells are all connected to the deep N-well, and are sequentially connected to one DNW. A P-well in an “m^{th}” memory row is connected to a word line WLm, and “m” represents a row number. Wells in one row are combined, so that the memory cells in the array can be packaged more tightly because space between most wells is eliminated. The memory array is built in the same substrate as a logic circuit on another chip, and the logic circuit requires the substrate to be grounded or to be at 0 V.

FIG. 5 shows bias voltages of the above array in programming and readout modes. Each memory cell in the array 250 may be programmed or erased independently. Therefore, the memory array 250 can be used to form a large electrically erasable programmable memory (EEPROM) that is different from a flash memory in which all cells in a page are erased together. Alternatively, the memory array 250 may form a flash memory by programming or erasing the cells in the array 250 together.

A specified memory cell may be separately programmed. During the programming, electrons are injected into a floating gate of a selected cell through band-to-band tunneling, resulting in a decrease in a threshold voltage of the first PMOS transistor in the memory cell, so that it is easier to turn on the transistor, and a readout current during a readout operation is caused to increase.

For example, the memory cell 200 may be programmed by driving a WL 0 to a VPP, a BL 0 to float, and a COM 0 to 0 V. A potential of the N-well and a potential of the deep N-well are the VPP. The VPP is 10.5 V. A programming process of the memory cell 200 is the same as that of the memory cell 100.

The COM 1 of the memory cell 210 floats. Therefore, in the first PMOS transistor of the memory cell 210, there is no reverse bias voltage on a PN junction between the N-well and a source of the transistor, electrons that may undergo tunneling cannot be formed in the PN junction, and a strong electric field that can excite the electrons to undergo tunneling cannot be created between the floating gate and the source. Therefore, the cell 210 cannot be programmed. The WL 1 of the cell 220 floats, and a strong electric field that can excite electrons to undergo tunneling cannot be created between the floating gate and a source of the first PMOS transistor of the cell 220. Therefore, the cell cannot be programmed. The COM 1, the BL 1, and the WL 1 of the cell 230 are all in a floating state, and the cell cannot be programmed, either.

During the programming, the deep N-well is driven to a VPP to ensure that all junctions in the array 250 are reverse-biased.

During a readout operation, data in a row of memory cells may be read out simultaneously. PMOS transistors in programmed and unprogrammed cells have threshold voltages of approximately 0 V and −1.5 V, respectively. In an implementation, a memory cell in a row 0 is selected for the readout operation, the cell 200 is in a programmed state, and the other cells are unprogrammed. Then, all common lines (COM) are driven to 1.2 V, all bit lines (BL) are precharged to 0 V, and the N-well and the deep N-well are driven to 1.5 V. An unselected word line is driven to 1.5 V, but the selected word line WL 0 is driven to 0 V.

As a result, the PMOS transistor 202 in the cell 200 is turned on, to pull the BL 0 up to 1.2 V. However, the PMOS transistor 212 in the cell 210 remains off and the BL 1 is still at 0 V because a negative threshold voltage of the transistor 212 is less than the bias voltage of the floating gate. A high voltage in the BL 0 is then detected by a sense amplifier and is driven to output a data signal of a state “1”. Similarly, a low state of the BL 1 is detected by another amplifier and is driven to output another signal of a state “0”. It is noted that regardless of programming states of transistors of a cell in an unselected row, the transistors are turned off due to high word line voltages of the transistors. Therefore, the transistors have no effect on the bit line.

In the array, a specified memory cell may also be erased. Erasing may be performed in a conventional manner, for example, Fowler-Nordheim tunneling. During the erasing operation, electrons are removed from a floating gate of the selected cell, thereby causing the threshold voltage of the PMOS transistor to increase, making the PMOS transistor more difficult to be turned on, and causing the readout current during the readout operation to decrease.

For example, the memory cell 200 may be erased by driving the WL 0 to −5V, the BL 0 and the COM 0 to 5V, and the potential of the N-well and the potential of the deep N-well are 5 V. Under the bias condition, a lower plate of the NMOS capacitor 201 forms an inversion layer, and the floating gate is coupled to a potential of about-4.7 V. In the case that the source and the drain of the transistor are driven to 5 V, an inversion layer is also formed in a channel region of the PMOS transistor 202. The inversion channel connects the source and the drain and receives a voltage of 5 V. As a result, a total voltage applied to a gate oxide of the PMOS transistor 202 is about 9.7 V, thereby forming a high electric field sufficient to cause electrons trapped in the floating gate to tunnel to an inversion channel filled with positive carriers. The high electric field may exceed about 10 MeV, and a tunneling mechanism is Fowler-Nordheim tunneling.

In this implementation, the WL 0 and the P-well 253B that are shared by the cells 200 and 210 can be driven to a negative potential value less than a substrate bias voltage (0 V) because the P-well 253B is separated from the substrate by the deep N-well 254. The deep N-well 254 is driven to 5 V during the erasing.

The memory cell 210 also receives a word line voltage of −5 V, but a source and a drain of the PMOS transistor 212 of the memory cell 210 receive a bias voltage of 0 V. As a result, a voltage across the gate oxide is only 4.7 V. Even if a channel of each of the readout transistor 212 and the NMOS capacitor 211 forms an inversion layer, the created electric field is not sufficient to trigger the Fowler-Nordheim tunneling. Therefore, the memory cell 210 is not affected during the erasing.

In the memory cell 220, a source and a drain of the transistor 222 are driven to 5 V, but a word line connected to the WL 1 receives a bias voltage of 0 V. As a result, a voltage across a gate oxide of the transistor 222 is only 4.7 V. Even if a channel of each of the readout transistor 222 and the NMOS capacitor 221 forms an inversion layer, the electric field is not sufficient to trigger the Fowler-Nordheim tunneling. Therefore, the memory cell 220 is not affected during the erasing.

In the memory cell 230, bias voltages of a word line, a source, and a drain of the transistor 232 are all 0 V. Therefore, an electric field through a gate oxide of the readout transistor 232 may be ignored, and the cell is not affected during erasing.

A readout operation after the erasing is the same as the readout operation after the programming. During the readout operation, data in a row of memory cells may be read out simultaneously. A first PMOS transistor in an erased cell has a threshold voltage of approximately-1.5 V.

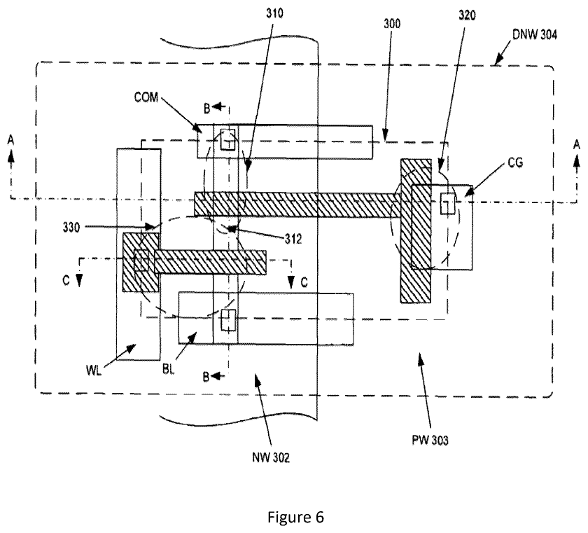

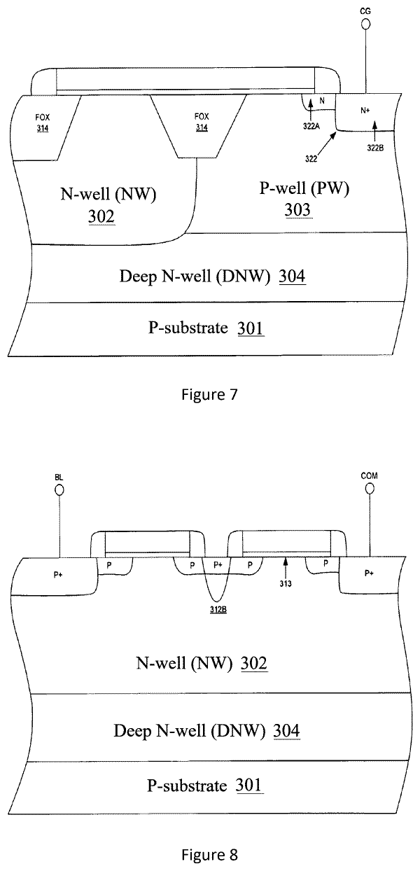

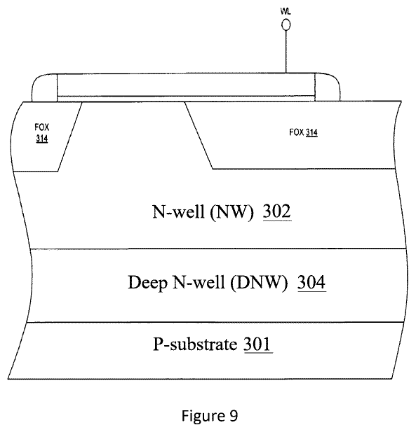

In another embodiment, a second PMOS transistor 330 is added and connected to a first PMOS transistor 310 in series, as shown in FIG. 6, forming another memory cell 300. The first PMOS transistor 310 is similar to the first PMOS transistor 110 of the non-volatile memory cell 100 in FIG. 1. FIG. 6 shows a top view of a non-volatile memory cell 300 with a second PMOS transistor 330. In different implementations, sectional views of FIG. 6 along section lines A-A, B-B, and C-C are respectively shown in FIG. 7, FIG. 8, and FIG. 9.

The non-volatile memory cell 300 includes an NMOS coupling capacitor 320, a first PMOS transistor 310, and a second PMOS transistor 330. The first PMOS transistor 310 includes a P-type drain region 312 that includes a lightly doped region 312A and a P+ contact region 312B. The drain P+ contact region 312B of the transistor 310 is shared by a source P+ contact region of the transistor 330. Therefore, the two PMOS transistors are connected in series. A source of the transistor 310 is connected to a common line (COM). In addition, the cell 300 includes a thick field oxide 314. A channel region 313 is located between the source and a drain of the transistor 310.

A bit line (BL) is connected to a drain of the transistor 330. A charge injection element 322 of the NMOS coupling capacitor 320 is connected to a control gate signal CG that is used to control a voltage of a floating gate during a storage operation. The charge injection element 322 includes a lightly doped N region 322A and a heavily doped N+ region 322B. A gate of the transistor 330 is connected to a word line (WL). In a manner of controlling a gate voltage by using the WL, the transistor 330 may be turned on or off, thereby connecting or disconnecting the transistor to or from the bit line BL. The source of the transistor 310 is connected to a common signal (COM), as in the memory cell 100. Similar to the memory cell 100, the NMOS coupling capacitor 320 is disposed in the P-well 303, and the PMOS transistors 310 and 330 are disposed in the N-well 302 adjacent to the P-well. Both the wells are located in the deep N-well (DNW) 304, and the deep N-well 304 is disposed in the P-type substrate 301.

When the memory cell 300 is programmed, similar to the memory cell 100, the source of the first PMOS transistor participates in the programming, and the drain does not. In addition, a drain of the second PMOS transistor floats, and the transistor does not participate in the programming. During the programming, the potential of the N-well and the potential of the deep N-well are driven to a VPP, the COM to 0 V, and the BL to float, and then the CG and the WL are driven to the VPP for programming. The VPP is 10.5 V. A programming process and a programming mechanism are the same as those of the memory cell 100.

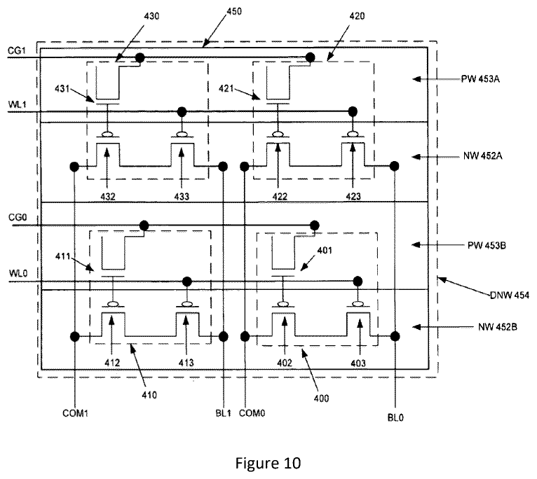

FIG. 10 shows a memory array 450 including four memory cells 300 arranged in two rows and two columns. Therefore, cells 420 and 430 form a memory row, and a WL and a CG line of the cells are respectively connected to the WL 1 and a CG 1. Similarly, cells 400 and 410 form another memory row, and a WL and a CG line of the cells are respectively connected to the WL 0 and a CG 0. The cells 400 and 420 form a column, and a common line and a bit line of the cells are respectively connected to the COM 0 and the BL 0. The cells 410 and 430 form another column, and a common line and a bit line of the cells are respectively connected to the COM 1 and the BL 1.

The memory array 450 is built in the P-type substrate. Deep N-wells of all the memory cells are combined, forming a single deep N-well 304. N-wells and P-wells of memory cells in a memory row are combined respectively. Therefore, each memory row includes one N-well (such as an NW 452A or an NW 452B) and one P-well (such as a PW 453A or a PW 453B).

The N-wells are all connected to the deep N-well, and are sequentially connected to one DNW 454. A P-well in an “m^{th}” memory row is connected to a word line CGm, and “m” represents a row number. Wells in one row are combined, so that the memory cells in the array can be packaged more tightly because space between most wells is eliminated. The memory array is built in the same substrate as a logic circuit on another chip, and the logic circuit requires the substrate to be grounded or to be at 0 V.

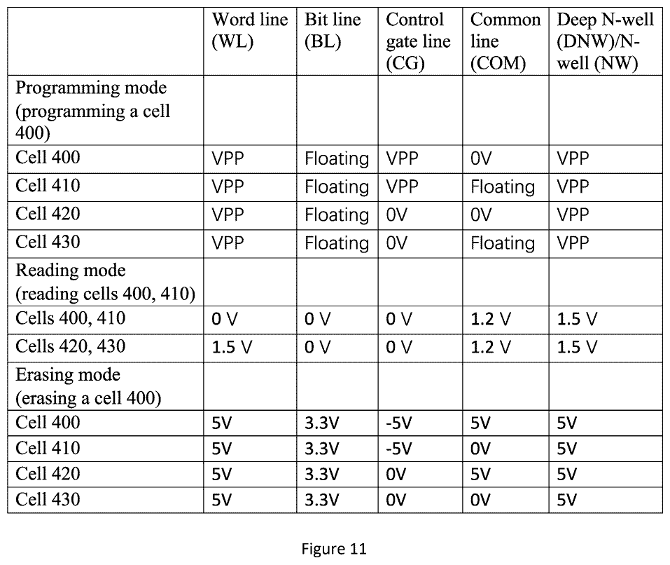

FIG. 11 shows bias voltages of the array 450 in programming and readout modes. Each memory cell in the array 450 may be programmed or erased independently. Therefore, the memory array 450 can be used to form a large electrically erasable programmable memory (EEPROM). Cells in the memory array 450 may alternatively be erased or programmed together in blocks, similar to a flash memory.

A specified memory cell in the array 450 may be used for programming. During the programming, electrons are injected into a floating gate of a selected cell, resulting in a decrease in a threshold voltage of a readout transistor, so that it is easier to turn on the transistor, and a readout current during a readout operation is caused to increase. During the programming, a deep N-well is driven to a VPP to ensure that all PN junctions in the array are reverse-biased.

Assuming that a memory cell 400 in the memory cell array 450 is selected, the memory cell 400 is programmed as follows: driving an N-well to a VPP and a COM 0 to 0 V, and driving a CG 0 and a WL 0 to the VPP, and a BL 0 to float. A programming process of the memory cell 400 is the same as that of the memory cell 300.

A COM 1 of a memory cell 410 floats. Therefore, in a first PMOS transistor 412 of the memory cell 410, there is no reverse bias voltage on a PN junction between the N-well and a source of the first PMOS transistor, and electrons that may undergo tunneling cannot be formed in the PN junction, and a strong electric field that can excite the electrons to undergo tunneling cannot be created between the floating gate and the source. Therefore, the cell 410 cannot be programmed. A CG 1 of a cell 420 is 0 V, and a strong electric field that can excite electrons to undergo tunneling cannot be created between a floating gate and a source of a first PMOS transistor 422 of the cell 420. Therefore, the cell cannot be programmed. A COM 1 of a cell 430 floats, a CG 1 is 0 V, and the cell cannot be programmed, either.

After the programming, in a readout operation of the array 450, data in a row of memory cells may be read out simultaneously. PMOS readout transistors in programmed and unprogrammed cells have threshold voltages of approximately 0 V and −1.5 V, respectively. In an implementation, when the cell 400 is in a programmed state, the cell 410 is in an unprogrammed state, and a row 0 is selected for the readout operation, the readout operation may be performed. Then, all common lines (COM) are driven to 1.2 V, all bit lines (BL) are precharged to 0 V, a coupling gate line (CG 0) is driven to 0 V, and the N-well and the DNW are driven to 1.5 V. An unselected word line is driven to 1.5 V, but the selected word line WL 0 is driven to 0 V. As a result, both the second transistor 403 and the first transistor 402 in the cell 400 are turned on, and the BL 0 is pulled up to 1.2 V.

In the cell 410, the second transistor 413 is turned on, but the first transistor 412 is cut off because the transistor 412 is in an unprogrammed state and the negative threshold voltage is less than the voltage of the floating gate. Therefore, the BL 1 remains at 0 V. A high voltage in the BL 0 is then detected by a sense amplifier and is driven to output a data signal of a state “1”. Similarly, a low state of the BL 1 is detected by another amplifier and is driven to output another signal of a state “0”. It is noted that a transistor of a cell in an unselected row is in a cutoff state, thereby causing the cell to be disconnected from the bit line.

In the array, a specified memory cell may also be erased. Erasing may be performed in a conventional manner, for example, Fowler-Nordheim tunneling. During the erasing operation, electrons are removed from a floating gate of the selected cell, thereby causing the threshold voltage of the PMOS transistor to increase, making the PMOS transistor more difficult to be turned on, and causing the readout current during the readout operation to decrease.

For example, the memory cell 400 may erased as follows: The CG 0 is driven to −5 V, the WL 0 is driven to 5 V, the BL 0 is driven to 3.3 V, the COM 0 is driven to 5 V, and a potential of the N-well and a potential of the deep N-well are 5 V. As a result, the second transistor 403 is cut off, thereby disconnecting the first transistor 402 from the BL 0. An NMOS capacitor 401 is in strong inversion, and an inversion layer is formed in a lower plate. The floating gate is coupled to about-4.7 V. In the case that a source of the first PMOS transistor 402 is driven to 5 V, an inversion layer is also formed in a channel region of the PMOS transistor 402. In the case that the drain of the transistor 402 is separated from the BL 0, the transistor 402 is in a linear region. The inversion channel connects the source and the drain and receives a voltage of 5 V. Therefore, a total voltage applied to a gate and/or a tunnel oxide is about 9.7 V, thereby creating a high electric field that may exceed about 10 MeV, and penetrating the tunnel oxide. This allows a majority of electrons trapped in the floating gate to gain enough energy to tunnel to an inversion channel and to be recombined with holes. A mechanism is Fowler-Nordheim tunneling.

In this implementation, the CG 0 and the P-well that are shared by the cells 400 and 410 can be driven to a negative potential value less than a substrate bias voltage (0 V) because the P-well is separated from a substrate by a deep N-well. The deep N-well is driven to 5 V during the erasing. The memory cell 410 also receives a voltage of −5 V of the CG 0, but a source of a first PMOS transistor 412 of the memory cell 410 receives a bias voltage of 0 V. As a result, a voltage across the gate oxide is only 4.7 V. Even if a channel of each of the transistor 412 and an NMOS capacitor 411 forms an inversion layer, the created electric field is not sufficient to trigger the Fowler-Nordheim tunneling. Therefore, the memory cell 410 is not affected during the erasing.

In a memory cell 420, a source of a first PMOS transistor is driven to 5 V, but a coupling gate connected to the CG 1 receives a bias voltage of 0 V. As a result, a voltage across a gate oxide of the first PMOS transistor is only 4.7 V. Even if a channel of each of the first PMOS transistor 422 and an NMOS capacitor 421 forms an inversion layer, the electric field is not sufficient to trigger the Fowler-Nordheim tunneling. Therefore, erasing disturbance on the memory cell 420 is negligible.

In a memory cell 430, bias voltages of a CG and a source of a first PMOS transistor 432 are all 0 V. Therefore, an electric field through a gate oxide of the transistor 432 may be ignored, and a tunneling current in the transistor 432 may be ignored. Therefore, erasing disturbance in the cell 430 is not significant.

A readout operation after the erasing is the same as the readout operation after the programming of the array. During the readout operation, data in a row of memory cells may be read out simultaneously. A first PMOS transistor in an erased cell has a threshold voltage of approximately −1.5 V.

It may be appreciated that the various operations, processes, and methods described herein may be specifically embodied in a machine-readable medium and/or a machine-accessible medium compatible with a data processing system (for example, a computer system), and may be implemented in any sequence (including, for example, using methods to implement various operations). Accordingly, the specification and the accompanying drawings should be considered to be illustrative only and not limiting.

What is claimed is:

1. A programming method for a non-volatile memory, the memory comprising:
at least one non-volatile memory cell built on a P-type substrate, wherein each non-volatile memory cell comprises:
a deep N-well located in the P-type substrate, wherein a P-well and an N-well are located in the deep N-well;
a first P-channel Metal Oxide Semiconductor (PMOS) transistor located in the N-well;
an N-channel metal oxide semiconductor (NMOS) capacitor located in the P-well, wherein the NMOS capacitor comprises an N+ coupling region located in the P-well; and
a floating gate covering the first PMOS transistor and the NMOS capacitor,
wherein the programming method is: programming the first PMOS transistor in the non-volatile memory cell through band-to-band tunneling, the programming method comprising the following steps:
(a) causing a potential of the N-well to be greater than a potential of a terminal of the first PMOS transistor, wherein a potential difference between the N-well and the terminal forms a reverse bias voltage on a PN junction at an interface between the N-well and the terminal, and the reverse bias voltage causes electrons in the PN junction to concentrate on a side of the PN junction that is close to the N-well;
(b) causing a potential on the floating gate of the first PMOS transistor to be greater than a potential of the terminal of the first PMOS transistor, wherein a potential difference between the floating gate of the first PMOS transistor and the terminal of the first PMOS transistor creates a strong electric field with an electric field strength greater than 8 MV/cm between the floating gate and the terminal; and
(c) implementing the programming by injecting, into the floating gate of the first PMOS transistor, the electrons on the side of the PN junction that is close to the N-well at the interface between the N-well and the terminal, under an action of the strong electric field.

2. The programming method according to claim 1, wherein the potential difference between the N-well and the terminal is less than an avalanche breakdown voltage of the PN junction at the interface between the N-well and the terminal.

3. The programming method according to claim 2, wherein the potential difference between the N-well and the terminal is 0.1 V to 1.0 V less than the avalanche breakdown voltage of the PN junction at the interface between the N-well and the terminal.

4. The programming method according to claim 1, wherein the potential on the floating gate of the first PMOS transistor is obtained by coupling a potential applied to the N+ coupling region of the NMOS capacitor, and the potential applied to the N+ coupling region is less than or equal to the potential of the N-well.

5. The programming method according to claim 4, wherein the potential applied to the N+ coupling region is equal to the potential of the N-well.

6. The programming method according to claim 1, wherein the terminal of the first PMOS transistor that participates in the programming is a source of the first PMOS transistor, and has a potential of 0 V during the programming; and another terminal of the first PMOS transistor is a drain that is in a floating state during the programming.

7. The programming method according to claim 1, wherein a capacitance of the NMOS capacitor is greater than a gate capacitance of the first PMOS transistor.

8. The programming method according to claim 1, wherein the non-volatile memory cell further comprises a second PMOS transistor located in the N-well, wherein a drain of the first PMOS transistor is coupled to a source of the second PMOS transistor, and a drain of the second PMOS transistor does not participate in the programming.

9. The programming method according to claim 8, wherein the drain of the second PMOS transistor is in a floating state during the programming.

10. The programming method according to claim 9, wherein a potential of a gate of the second PMOS transistor is the same as the potential of the N-well during the programming.

11. The programming method according to claim 8, wherein a channel of the second PMOS transistor is not conducting during the programming.

12. The programming method according to claim 1, wherein the floating gate in the memory cell is a single-layer polysilicon gate.

13. The programming method according to claim 1, wherein the non-volatile memory is an electrically erasable programmable non-volatile memory.

14. A non-volatile memory comprising:
at least one non-volatile memory cell built on a P-type substrate, wherein each non-volatile memory cell comprises:
a deep N-well located in the P-type substrate, wherein a P-well and an N-well are located in the deep N-well;
a first P-channel Metal Oxide Semiconductor (PMOS) transistor located in the N-well;
an N-channel metal oxide semiconductor (NMOS) capacitor located in the P-well, wherein the NMOS capacitor comprises an N+ coupling region located in the P-well; and
a floating gate covering the first PMOS transistor and the NMOS capacitor; and
a programming circuit, configured to:
(a) cause a potential of the N-well to be greater than a potential of a terminal of the first PMOS transistor, wherein a potential difference between the N-well and the terminal forms a reverse bias voltage on a PN junction at an interface between the N-well and the terminal, and the reverse bias voltage causes electrons in the PN junction to concentrate on a side of the PN junction that is close to the N-well;
(b) cause a potential on the floating gate of the first PMOS transistor to be greater than a potential of the terminal of the first PMOS transistor, wherein a potential difference between the floating gate of the first PMOS transistor and the terminal of the first PMOS transistor creates a strong electric field with an electric field strength greater than 8 MV/cm between the floating gate and the terminal; and
(c) implement the programming by injecting, into the floating gate of the first PMOS transistor, the electrons on the side of the PN junction that is close to the N-well at the interface between the N-well and the terminal, under an action of the strong electric field.

15. The non-volatile memory according to claim 14, wherein the potential difference between the N-well and the terminal is less than an avalanche breakdown voltage of the PN junction at the interface between the N-well and the terminal.

16. The non-volatile memory according to claim 15, wherein the potential difference between the N-well and the terminal is 0.1 V to 1.0 V less than the avalanche breakdown voltage of the PN junction at the interface between the N-well and the terminal.

17. The non-volatile memory according to claim 14, wherein the potential on the floating gate of the first PMOS transistor is obtained by coupling a potential applied to the N+ coupling region of the NMOS capacitor, and the potential applied to the N+ coupling region is less than or equal to the potential of the N-well.

18. The non-volatile memory according to claim 17, wherein the potential applied to the N+ coupling region is equal to the potential of the N-well.

19. The non-volatile memory according to claim 18, wherein the terminal of the first PMOS transistor that participates in the programming is a source of the first PMOS transistor, and has a potential of 0 V during the programming; and another terminal of the first PMOS transistor is a drain that is in a floating state during the programming.

20. The non-volatile memory according to claim 19, wherein a capacitance of the NMOS capacitor is greater than a gate capacitance of the first PMOS transistor.
